(19) United States
(12) Patent Application Publication
(10) Pub. No.: US 2024/0355615 A1
(43) Pub. Date: Oct. 24, 2024

(54) METHOD AND APPARATUS FOR PROCESSING SUBSTRATE

(71) Applicant: Tokyo Electron Limited, Tokyo (JP)

(72) Inventors: Tadahiro ISHIZAKA, Nirasaki City (JP); Takashi SAKUMA, Nirasaki City (JP)

(21) Appl. No.: 18/638,991

(22) Filed: Apr. 18, 2024

(30) Foreign Application Priority Data
Apr. 20, 2023 (JP) 2023-069426

(51) Int. Cl. H01L 21/02; H01J 37/32; H01L 21/67; H01L 21/768

(52) U.S. Cl. CPC H01L 21/02068; H01J 37/32899; H01L 21/67069; H01L 21/76877; H01J 2237/335; H01L 21/67155

(57) ABSTRACT

A method of processing a substrate includes: removing a silicon oxide portion contained in an oxide film on a surface of a metal silicide layer by supplying a hydrogen fluoride gas and an ammonia gas to the oxide film so as to react with the silicon oxide portion contained in the oxide film, wherein the metal silicide layer is provided by being stacked in a recess formed in an insulator layer which is stacked on a silicon-containing layer; and removing a metal oxide portion by supplying a metal halide gas to the oxide film so as to react with the metal oxide portion contained in the oxide film.

### CROSS-REFERENCE TO RELATED APPLICATION

This application is based upon and claims the benefit of priority from Japanese Patent Application No. 2023-069426, filed on Apr. 20, 2023, the entire contents of which are incorporated herein by reference.

### TECHNICAL FIELD

The present disclosure relates to a method and apparatus for processing a substrate.

### BACKGROUND

In a semiconductor device manufacturing process, there is a process in which a recess such as a via hole or a trench is formed in an insulating layer formed on a semiconductor wafer (hereinafter, also referred to as a “wafer”) as a substrate, and a conductor as a wiring material is formed in the recess. At this time, a natural oxide film may be formed on a surface of a metal exposed in the recess due to contact with air. When the conductor is embedded without removing such a natural oxide film, wiring resistance may be increased.

Patent Document 1 discloses a technique for etching a substrate including a metal oxide layer, which may contain Si and one or more metals gases selected from the group consisting of alkali metals, alkaline earth metals, transition metals, lanthanides, actinides, and late transition metals, by exposing the substrate to a metal halide. In addition, Patent Document 2 discloses a technique for exposing an oxide layer containing one or more of hafnium, tungsten, molybdenum, and titanium to a fluorinating agent to form a fluoride layer, and then exposing the fluoride layer to a halide etchant to remove the fluoride layer.

However, in these patent documents, there is no description of a technique specifically effective in removing an oxide film of metal silicide.

### PRIOR ART DOCUMENTS

### Patent Documents

Patent Document 1: Japanese Patent Laid-Open Publication No. 2021-507509
Patent Document 2: Japanese Patent Laid-Open Publication No. 2022-536475

### SUMMARY

According to one embodiment of the present disclosure, a method of processing a substrate includes: removing a silicon oxide portion contained in an oxide film on a surface of a metal silicide layer by supplying a hydrogen fluoride gas and an ammonia gas to the oxide film so as to react with the silicon oxide portion contained in the oxide film, wherein the metal silicide layer is provided by being stacked in a recess formed in an insulator layer which is stacked on a silicon-containing layer; and removing a metal oxide portion by supplying a metal halide gas to the oxide film so as to react with the metal oxide portion contained in the oxide film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a configuration example of a substrate processing apparatus according to an embodiment.

FIG. 2 is a vertical cross-sectional side view illustrating a configuration example of a Ti film forming module provided in the substrate processing apparatus.

FIG. 3 is an explanatory view illustrating an example of a flow of wafer processing according to an embodiment.

FIG. 4A is a first enlarged cross-sectional side view of a surface of a wafer on which a process according to an embodiment is performed.

FIG. 4B is a second enlarged cross-sectional side view of the surface of the wafer.

FIG. 4C is a third enlarged cross-sectional side view of the surface of the wafer.

FIG. 4D is a fourth enlarged cross-sectional side view of the surface of the wafer.

FIG. 4E is a fifth enlarged cross-sectional side view of the surface of the wafer.

FIG. 4F is a sixth enlarged cross-sectional side view of the surface of the wafer.

FIG. 5 is a plan view illustrating a configuration example of a substrate processing apparatus according to a second embodiment.

FIG. 6 is an explanatory view illustrating an example of a flow of wafer processing according to the second embodiment.

FIG. 7 is a plan view illustrating a configuration example of a substrate processing apparatus according to a third embodiment.

FIG. 8 is an explanatory view illustrating an example of a flow of wafer processing according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Substrate Processing Apparatus 1>

Hereinafter, an embodiment of an apparatus (hereinafter, referred to as a “substrate processing apparatus 1”) having a function of removing an oxide film (a MoSiOₓ layer 65a) on a surface of a MoSi layer 64, which is a metal silicide layer, and forming a Ru film 67, which is a conductor, will be described.

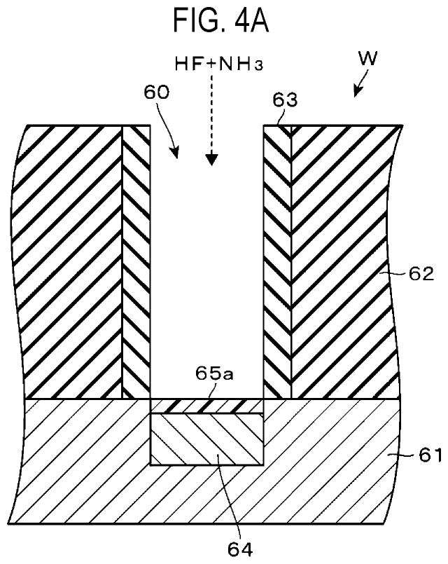

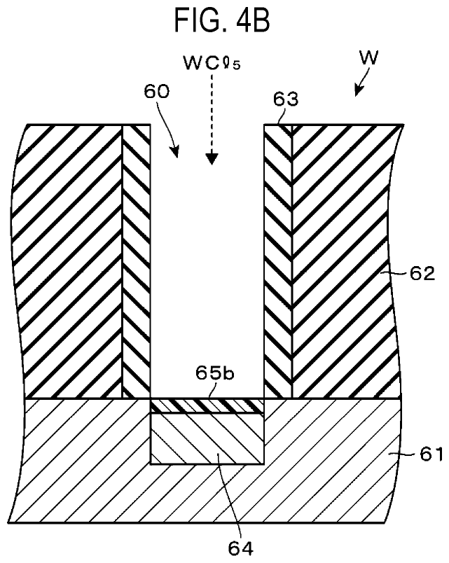

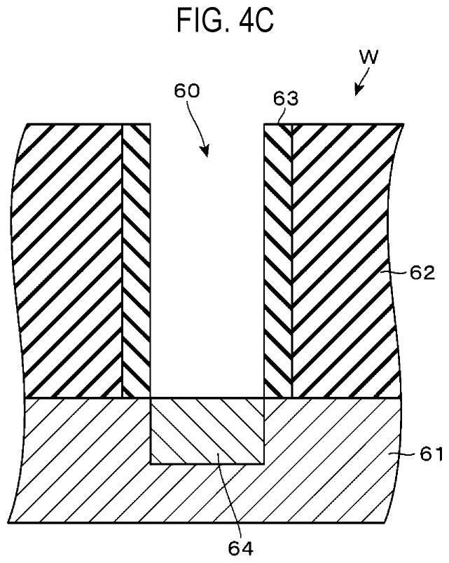

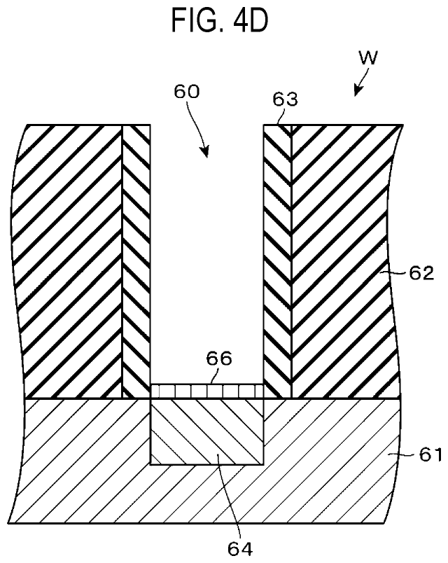

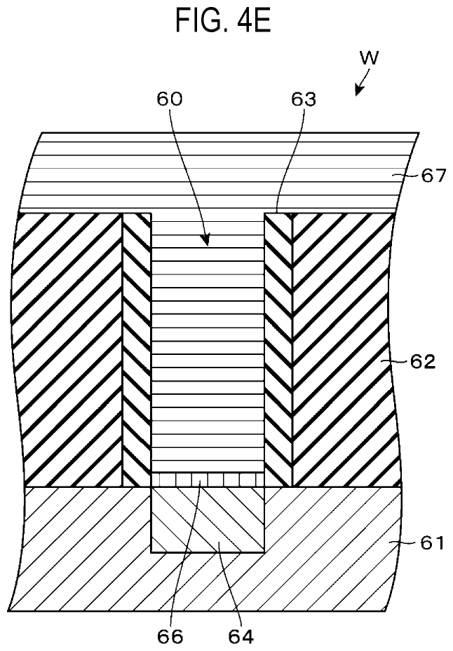

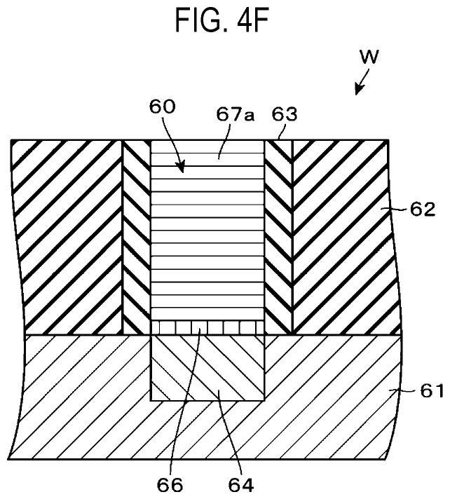

Before describing a configuration of the substrate processing apparatus 1, an example of a surface structure of a wafer W to be processed in the substrate processing apparatus 1 will be described. As illustrated in FIG. 4A, in the wafer W to be processed, an SiO layer 62 is stacked on a SiGe layer 61, which is a silicon-containing layer, and a recess 60 is formed in the SiO layer 62 to embed ruthenium (Ru), which is a conductor. A molybdenum (Mo) layer for adjusting a Schottky barrier height is formed at a bottom of the recess 60, and is turned into the MoSi layer 64 by diffusion of silicon (Si) from the SiGe layer 61.

When the wafer W having the above-described configuration is transferred in a semiconductor manufacturing factory toward the substrate processing apparatus 1, the MoSiOₓ layer 65a, which is an oxide film, is formed on the surface of the MoSi layer 64 due to contact with the air. Therefore, the substrate processing apparatus 1 of the present embodiment is configured to embed Ru after removing the MoSiOₓ layer 65a.

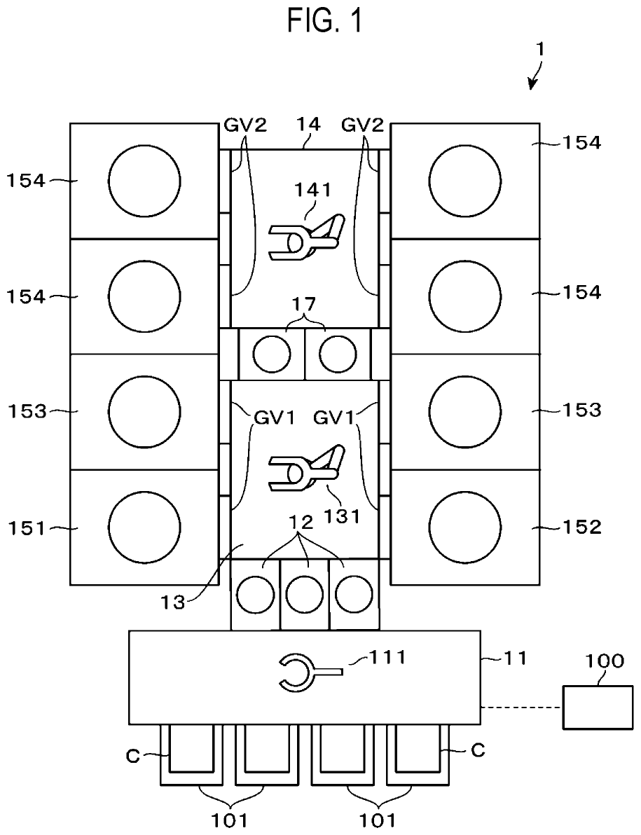

FIG. 1 is a schematic plan view illustrating a configuration example of the substrate processing apparatus 1. This substrate processing apparatus 1 includes an atmospheric transfer chamber 11, a load-lock chamber 12, a first substrate transfer chamber 13, a second substrate transfer chamber 14, and a plurality of processing modules 151 to 154.

The first substrate transfer chamber 13 and the second substrate transfer chamber 14 are configured to have a square shape in a plan view, and are connected to each other via, for example, two delivery parts 17. Interiors of the first and second substrate transfer chambers 13 and 14 and the delivery parts 17 are kept in a vacuum pressure atmosphere. The first and second substrate transfer chambers 13 and 14 and the delivery parts 17 are configured to be equalized in pressure to each other. Further, first and second transfer mechanisms 131 and 141 are arranged inside the first and second substrate transfer chambers 13 and 14, respectively.

The delivery parts 17 delivers the wafer to and from the first transfer mechanism 131 provided in the first substrate transfer chamber 13 or to and from the second transfer mechanism 141 provided in the second substrate transfer chamber 14. The first substrate transfer chamber 13, the second substrate transfer chamber 14, and the delivery parts 17 correspond to the vacuum transfer chamber of the present embodiment. Further, the first transfer mechanism 131 and the second transfer mechanism 141 correspond to the substrate transfer mechanism of the present embodiment.

A direction where the first substrate transfer chamber 13 and the second substrate transfer chamber 14 are arranged will be referred to as a length direction, a place in which the first substrate transfer chamber 13 is positioned will be referred to as a front side and a place in which the second substrate transfer chamber 14 is positioned will be referred to as a rear side. In this case, the atmosphere transfer chamber 11 kept in the atmospheric pressure atmosphere is connected to the front side of the first substrate transfer chamber 13 via, for example, three load-lock chambers 12. Wafer transfer ports (not illustrated) and gate valves (not illustrated) for opening/closing the transfer ports are respectively provided between the first and second substrate transfer chambers 13 and 14 and the delivery parts 17, between the load-lock chambers 12 and the first substrate transfer chamber 13, and between the load-lock chambers 12 and the atmospheric transfer chamber 11.

For example, four load ports 101 are connected to the atmospheric transfer chamber 11, and a carrier C accommodating a plurality of wafers W is placed on each load port 101. The atmospheric transfer chamber 11 includes an atmospheric transfer mechanism 111 to transfer the wafers W between the carriers C connected to the atmospheric transfer chamber 11 and the load-lock chambers 12.

When viewed from the front side, one oxide removal (chemical oxide removal (COR)) module 151, one heat treatment (post heat treatment (PHT)) module 152 and two Ti film forming modules 153 are connected to two left and right walls of the first substrate transfer chamber 13. In addition, the first transfer mechanism 131 provided in the first substrate transfer chamber 13 is configured to transfer the wafers W among these four modules 151 to 153, the delivery parts 17, and the load-lock chambers 12. In FIG. 1, reference numerals GV1 indicate gate valves.

The COR process performed by the COR module 151 and the PHT process performed by the PHT module 152 are pre-cleaning processes that remove silicon oxide contained in the above-described MoSiOₓ layer 65a. Here, the MoSiOₓ layer 65a is configured as a composite oxide containing Si, Mo, and oxygen (O). In the present disclosure, an oxidized portion of Si (SiOₓ) contained in the composite oxide is referred to as a “silicon oxide portion”, and an oxidized portion of Mo (MoOₓ) contained in the composite oxide is also referred to as a “molybdenum oxide portion”. In the MoSiOₓ layer 65a, which is an oxide film of the metal silicide layer, the “molybdenum oxide portion” corresponds to the “metal oxide portion” of the metal silicide layer.

The COR module 151 is configured to perform an etching process (COR process) on the natural oxide film using a hydrogen fluoride (HF) gas and an ammonia (NH₃) gas. In addition, the PHT module 152 is configured to perform the PHT process in which reaction products generated in the COR process are sublimated and removed by heating the wafer W. Configuration examples of the COR module 151 and PHT module 152 will be described later. The COR module 151 corresponds to a first processing module of the present embodiment.

Further, each of the Ti film forming module 153 is configured to form a Ti layer 66, which is a contact metal layer provided between the MoSi layer 64 and a Ru wire 67a. In addition, the Ti film forming modules 153 of the present embodiment also have a function of removing the MoSiOₓ layer 65a after the removal of the silicon oxide component by the COR process and the PHT process (hereinafter, the MoSiOₓ layer 65a is also referred to as “MoOₓ layer 65b” since SiOₓ has already been removed). The MoOₓ layer 65b corresponds to the metal oxide portion of the present embodiment. In addition, from the viewpoint of removing the MoOₓ layer 65b, the Ti film forming modules 153 correspond to a second processing module of the present embodiment.

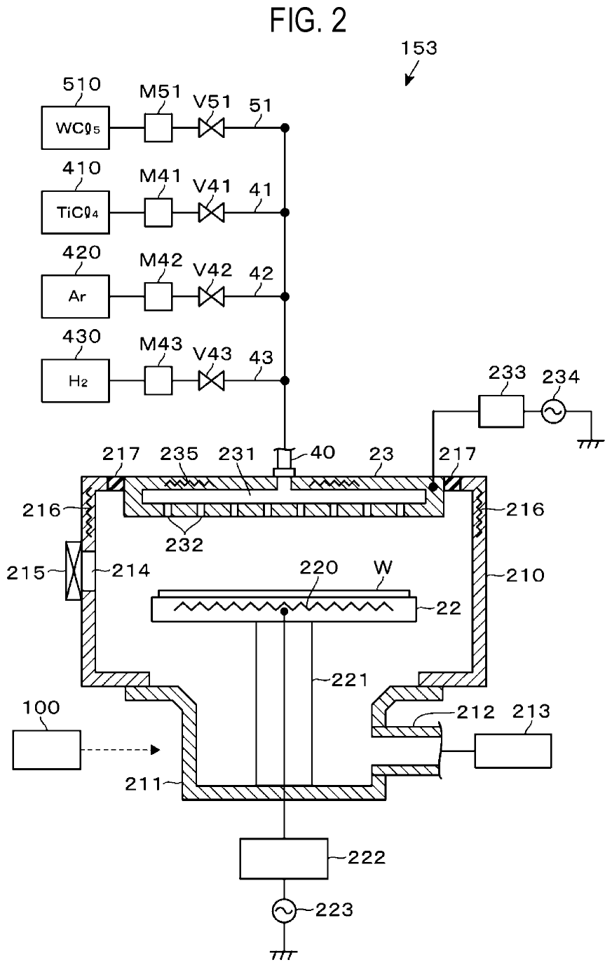

A specific configuration example of the Ti film forming modules 153 will be described later with reference to FIG. 2.

In addition, when viewed from the front side, a total of four Ru film forming modules 154 are connected two-by-two to two left and right walls of the second substrate transfer chamber 14. The second transfer mechanism 141 is configured to transfer the wafers W among these four Ru film forming modules 154 and the delivery parts 17. In FIG. 1, the symbol GV2 indicates gate valves.

Each Ru film forming module 154 is configured to form the Ru film 67 with a raw material gas of Ru as a conductor by, for example, a chemical vapor deposition (CVD) method. The Ru film forming module 154 corresponds to a fourth processing module of the present embodiment.

### <Ti Film Forming Module 153>

Next, a specific configuration example of the Ti film forming module 153 will be described with reference to FIG. 2. The Ti film forming module 153 is configured to supply a film forming gas to the wafer W and form the Ti layer 66 by plasma CVD. The Ti film forming module 153 also has a function of removing a remaining MoOₓ layer 65b by supplying a metal halide gas to the wafer W from which the silicon oxide component of the MoSiOₓ layer 65a has been removed.

FIG. 2 is a vertical cross-sectional side view of the Ti film forming module 153 of the present embodiment. The Ti film forming module 153 includes a substantially cylindrical metal processing container 210 that is resistant to corrosion against chlorine and is grounded. For example, a cylindrical exhaust chamber 211, which protrudes downward, is formed in the center of a bottom of the processing container 210, and an exhaust path 212 is connected to a side surface of the exhaust chamber 211. The exhaust path 212 is connected to a vacuum exhauster 213, which includes a pressure regulating valve such as a butterfly valve and a vacuum pump. The vacuum exhauster 213 serves to evacuate an interior of the processing container 210 until the interior of the processing container 210 has a preset vacuum pressure. The wafer W is processed in a space in the interior of the processing container 210.

A loading/unloading port 214 is formed in the side surface of the processing container 210 to load/unload the wafer W into/from the above-described first substrate transfer chamber 13. This loading/unloading port 214 is configured to be openable/closable by a gate valve 215 (GV1 in FIG. 1). Further, a heater 216 configured to adjust an internal temperature of the processing container 210 is embedded in a wall portion of the processing container 210.

In addition, a stage 22 configured to hold the wafer W substantially horizontally is provided inside the processing container 210. The stage 22 is supported by a support 221 extending from a bottom of the exhaust chamber 211. A heater 220 as a heating part may be embedded in the stage 22 to heat the wafer W to a set temperature. In the present example, a heating temperature of the wafer W is set within a range of 350 to 800 degrees C., for example, 450 degrees C.

In addition, a radio-frequency power source 223 configured to supply radio-frequency power for ion attraction is connected to the stage 22 via a matcher 222. Further, the stage 22 is provided with lifting pins (not illustrated) configured to raise/lower the wafer W while holding the wafer W on the stage 22. The wafer W may be transferred between the stage 22 and the first transfer mechanism 131 in the first substrate transfer chamber 13 by raising/lowering the lift pins.

In addition, a flat disk-shaped shower head 23 configured to supply a substrate processing gas toward the wafer W is provided on a ceiling surface of the processing container 210. The shower head 23 is attached to the processing container 210 via an insulating member 217.

A diffusion chamber 231 configured to diffuse a gas is formed inside the shower head 23. In addition, a large number of ejection holes 232 through which a gas is discharged toward the wafer W are provided in a distributed manner on a bottom surface of the shower head 23. Further, a heater 235 is embedded in an upper surface of the shower head 23.

A radio-frequency power source 234 configured to supply radio-frequency power for plasma formation is connected to the above-mentioned shower head 23 via a matcher box 233. That is, the substrate processing apparatus 1 of the present embodiment constitutes a parallel plate-type plasma processing apparatus by the shower head 23 serving as an upper electrode and the stage 22 serving as a lower electrode. By placing the wafer W in a space between the shower head 23 and the stage 22, supplying the film forming gas, and applying the radio-frequency power, the gas is ionized to form plasma. The radio-frequency power source 234 may be configured to supply the radio-frequency power of a frequency of 450 KHz, 13.56 MHz, 27 MHz, 40 MHz, 60 MHz, 100 MHz, or 2.45 GHz. For example, the radio-frequency power source 234 supplies the radio-frequency power which is greater than 0 W and equal to or lower than 2,000 W.

In addition, a downstream end of the gas supply path 40 is connected to the diffusion chamber 231 of the shower head 23. A TiCl₄ gas supply pipe 41, which is a flow path for supplying a TiCl₄ gas constituting the film forming gas for the Ti layer 66, an Ar gas supply pipe 42, which is a flow path for supplying an Ar gas added for plasma generation, and a H₂ gas supply pipe 43, which is a flow path for supplying a H₂ gas as a reaction gas, are joined at an upstream side of the gas supply path 40.

A TiCl₄ gas source 410 is connected to an upstream end of the TiCl₄ gas supply pipe 41. A flow rate regulator M41 and a valve V41 are interposed in this order from an upstream side of the TiCl₄ gas supply pipe 41. In addition, an Ar gas source 420 is connected to an upstream end of the Ar gas supply pipe 42. A flow rate regulator M42 and a valve V42 are interposed in this order from an upstream side of the Ar gas supply pipe 42. Further, a H₂ gas source 430 is connected to an upstream end of the H₂ gas supply pipe 43. A flow rate regulator M43 and a valve V43 are interposed in this order from an upstream side of the H₂ gas supply pipe 43.

A mixed gas (film forming gas) of the TiCl₄ gas, the H₂ gas, and the Ar gas flows into the diffusion chamber 231 of the shower head 23 via the gas supply path 40, and is supplied into the processing container 210 via the ejection holes 232.

In addition, a WCl₅ gas supply pipe 51 is joined at the upstream side of the gas supply path 40. The WCl₅ gas corresponds to a metal halide gas for removing the MoOₓ layer 65b. A WCl₅ gas source 510 is connected to an upstream end of the WCl₅ gas supply pipe 51. A flow rate regulator M51 and a valve V51 are interposed in this order from an upstream side of the WCl₅ gas supply pipe 51. The WCl₅ gas source 510 configured to supply the WCl₅ gas, the flow rate regulator M51, and the like constitute a metal halide gas supplier of the present embodiment. The WCl₅ gas also flows into the diffusion chamber 231 of the shower head 23 via the gas supply path 40 and is supplied into the processing container 210 via the ejection holes 232.

### <Other Processing Modules 151, 152, and 153>

Although not illustrated, the COR module 151, the PHT module 152, and the Ru film forming module 154 are similar to the above-described Ti film forming module 153 in that the modules includes the processing container 210 and the stage 22. In addition, in the COR module 151, a mixed gas of an HF gas and a NH₃ gas used for the COR process is supplied to the processing container 210 via the gas supply path 40. Gas sources which supply the HF gas and the NH₃ gas, a flow rate regulator, and the like constitute a mixed-gas supplier of the present embodiment.

In addition, in the PHT module 152, a N₂ gas, which forms an inert gas atmosphere where the PHT process is performed, is supplied to the processing container 210 via the gas supply path 40. In the PHT module 152, the wafer W is heated to, for example, 200 degrees C. in the range of 60 to 250 degrees C. by the heater 220 of the stage 22.

In addition, the COR module 151 or the PHT module 152 of the present embodiment is not provided with the radio-frequency power source 234 for plasma formation or the like.

Further, in the Ru film forming module 154, a Ru₃ (CO)₁₂ gas, which is a raw material gas for the Ru film 67, and a CO gas, which is a carrier gas, are supplied to the processing container 210 via the gas supply path 40. Gas sources which supply the Ru₃ (CO)₁₂ gas and the CO gas, a flow rate regulator, and the like correspond to a raw material gas supplier of the present embodiment. In addition, the Ru film forming module 154 of the present embodiment is configured to form the Ru film 67 by, for example, a thermal CVD method. Therefore, unlike the Ti film forming module 153 described with reference to FIG. 2, the Ru film forming module does not include the matcher 233 and the radio-frequency power source 234 connected to the shower head 23, and the matcher 222 and the radio-frequency power source 223 connected to the stage 22.

### <Controller 100>

The substrate processing apparatus 1 having the above-described configuration includes a controller 100 as illustrated in FIGS. 1 and 2. The controller 100 is constituted with a computer including a storage storing a program, a memory, and a CPU. The program includes instructions (steps) incorporated to execute substrate processing using various modules 151 to 154 by outputting control signals from the controller 100 to respective components of the substrate processing apparatus 1 to control the supply and cutoff of each gas and the supply of the radio-frequency power. The program is stored in the storage of the computer, such as a flexible disk, a compact disk, a hard disk, a magneto-optical (MO) disk, and a nonvolatile memory, and is read from the storage and installed in the controller 100.

### <Substrate Processing>

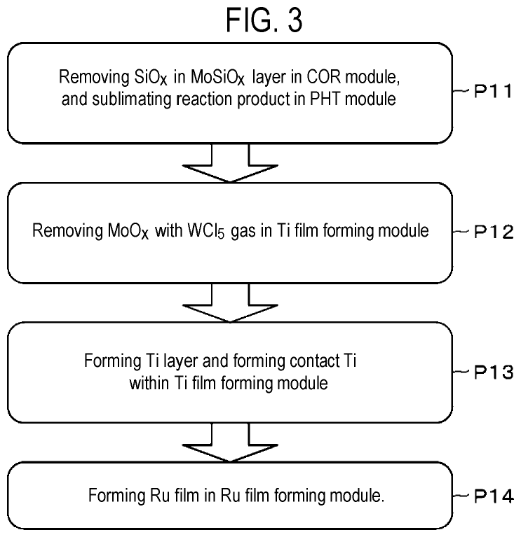

Details of the substrate processing to be performed by the substrate processing apparatus 1 configured as above will be described with reference to FIG. 3 and FIGS. 4A to 4F.

In the substrate processing apparatus 1, first, the atmospheric transfer mechanism 111 takes out the wafer W accommodated in the carrier C and transfers the same to the load-lock chamber 12 kept in the atmospheric pressure atmosphere, and the interior of the load-lock chamber 12 is regulated to be in a vacuum pressure atmosphere. Subsequently, the first transfer mechanism 131 transfers the wafer W in the load-lock chamber 12 to the COR module 151 and places the same on the stage 22 in the processing container 210.

In the COR module 151, the temperature of the wafer W placed on the stage 22 is regulated to 60 degrees C. or less, for example, 27 degrees C. Then, the mixed gas of the HF gas and the NH₃ gas is supplied from the aforementioned mixed-gas supplier to the wafer W in the processing container 210 (FIG. 4A). It is known that at a temperature below 60 degrees C., the probability of adsorption of molecules of the HF gas and the NH₃ gas to the wafer W is high. Therefore, the molecules of these gases are densely adsorbed on the surface of the wafer W, and also reach and adsorbed to the MoSiOₓ layer 65a formed on the bottom of the recess 60. As a result, a chemical reaction between the silicon oxide (SiOₓ) portion of the MoSiOₓ layer 65a and the HF molecules and the NH₃ molecules progresses to form reaction products, so that the silicon oxide portion is removed (etched) (Operation P11 in FIG. 3 (operation of removing the silicon oxide portion)).

The reaction products produced in the COR process include ammonium fluorosilicate ((NH₄)₂SiF₆) and water (H₂O). The reaction products are attached to the bottom and sidewall surfaces of the recess 60, the upper surface of the SiO layer 62, and the like. In addition, in this COR process, ammonium fluoride (NH₄F) is also produced by the reaction between the hydrogen fluoride gas and the ammonia gas. The molecules of this ammonium fluoride also act as an etchant and react with the silicon oxide portion to form reaction products. Further, in the COR process, ammonium fluoride itself may be deposited on the surface of the wafer W as a solid component.

The wafer W from which the silicon oxide has been removed by the COR process is transferred from the COR module 151 to the PHT module 152 and placed on the stage 22 in the processing container 210. In the PHT module 152, the wafer W is heated to sublimate and remove the reaction products and solid ammonium fluoride generated in the COR process. Specifically, the N₂ gas is supplied into the processing container 210, and the temperature of the wafer W placed on the stage 22 is regulated to 200 degrees C. As a result, the reaction products and solid ammonium fluoride attached to the heated wafer W sublimate, and the N₂ gas is discharged to the outside of the processing container 210 together (Operation P11 in FIG. 3 (operation of removing the reaction products)).

Subsequently, the first transfer mechanism 131 transfers the wafer W to the Ti film forming module 153. As described above, the Ti film forming module 153 executes two operations of removing the MoOₓ layer 65b (the metal oxide portion) remaining after the removal of the silicon oxide portion from the MoSiOₓ layer 65a, and forming the Ti layer 66.

First, when the wafer W is placed on the stage 22 of the Ti film forming module 153, the vacuum exhauster 213 evacuates the interior of the processing container 210 to a preset pressure. In addition, the wafer W is heated to 450 degrees C. by the heater 220 as described above. Thereafter, the WCl₅ gas is supplied from the metal halide gas supplier into the processing container 210 (FIG. 4B).

As illustrated in FIG. 4B, when the WCl₅ gas reaches the wafer W, the reaction represented in Equation (1) below proceeds.

2MoO₃(s)+2WCl₅(g)→WO₂Cl₂(g)+2MoO₂Cl₂(g)+WCl₂(s) (1)

Solid WCl₂ remains on the surface of the wafer W. When residue of chlorine is undesirable, the H₂ gas is supplied from the H₂ gas source 430 in addition to the supply of the WCl₅ gas so that the reaction represented in Equation (2) below proceeds.

WCl₂(s)+H₂(g)→W(s)+2HCl(g) (2)

By reacting the WCl₅ gas with the H₂ gas, chlorine is removed as the HCl gas, leaving only metallic tungsten (W) on the surface of the wafer W.

By proceeding with the above-mentioned Equation (1), the MoOₓ layer 65b remaining in the recess 60 after the COR process may be removed (Operation P12 in FIG. 3 (operation of removing the metal oxide portion)). As a result, as illustrated in FIG. 4C, the oxide on the surface of the MoSi layer 64 in the recess 60 (the MoSiOₓ layer 65a in FIG. 4A) is removed.

After completing the operation of removing the MoOₓ layer 65b, the Ti layer 66, which is a metal layer for contact, is formed. Specifically, the supply of the WCl₅ gas to the processing container 210 of the Ti film forming module 153 is stopped. Then, the TiCl₄ gas, the H₂ gas, and the Ar gas are supplied from respective gas sources 410, 420, and 430 at preset flow rates, respectively, while continuously heating the wafer W and regulating the internal pressure of the processing container 210. As a result, the film forming gas, which is a mixture of these gases, is introduced into the processing container 210. Further, by applying the radio-frequency power from the radio-frequency power source 234 to turn the film forming gas into plasma, the formation of a Ti film on the wafer W proceeds (Operation P13 in FIG. 3).

After the formation of the Ti film is performed for a preset period of time, the supply of the film forming gas and the application of the radio-frequency power are stopped. As a result, the Ti layer 66 is formed on the bottom surface of the recess 60, as illustrated in FIG. 4D.

Subsequently, the wafer W is transferred to the Ru film forming module 154 by the first transfer mechanism 131, the delivery part 17, and the second transfer mechanism 141. The inert gas is supplied to the first substrate transfer chamber 13, the delivery part 17, and the second substrate transfer chamber 14 to prevent the gas from diffusing from the film forming module. The pressure is controlled to, for example, 100 Pa in the range of 20 to 200 Pa. In addition, in order to prevent oxidation of the surface during the transfer, an ultimate degree of vacuum of a vacuum exhaust mechanism (not illustrated), which to evacuate these spaces (the first substrate transfer chamber 13, the delivery part 17, and second substrate transfer chamber 14) is set to 1.33×10⁻⁵ Pa or lower. In the Ru film forming module 154, the Ru film 67 is formed such that Ru is embedded in the upper surface of the Ti layer 66 formed in the recess 60 (Operation P14 in FIG. 3 (operation of embedding the conductor)).

Specifically, the wafer W is loaded into the processing container 210 of the Ru film forming module 154 and placed on the stage 22. The wafer W is heated to, for example, 150 degrees C. in the range of 130 to 200 degrees C. by the heater 220. In addition, the internal pressure of the processing container 210 is regulated, and the Ru₃ (CO)₁₂ gas (containing the CO gas as a carrier gas) is supplied into the processing container 210.

As a result, thermal CVD in which the Ru₃ (CO)₁₂ supplied into the processing container 210 is thermally decomposed on the wafer W proceeds. Then, by performing the thermal CVD for a preset period of time, the Ru film 67 may be embedded in the recess 60 from which the MoSiOₓ layer 65a has been removed, as illustrated in FIG. 4E.

After the formation of the Ru film 67 is completed, the wafer W is transferred to the load-lock chamber 12 by the second transfer mechanism 141, the delivery part 17, and the first transfer mechanism 131. Subsequently, after the internal atmosphere of the load-lock chamber 12 is switched to the atmospheric pressure atmosphere, the atmospheric transfer mechanism 111 returns the processed wafer W to the carrier C. The unloaded wafer W is polished by an external chemical mechanical polishing (CMP) device. Through this process, it is possible to obtain the wafer W in which the upper surface is removed and the Ru wire 67a is embedded in the recess 60, as illustrated in FIG. 4F.

According to the above-described embodiment, the oxide film (MoSiOₓ layer 65a) on the surface of the metal silicide layer (MoSi layer 64) formed in the recess 60 of the substrate may be removed. As a result, an increase in wire resistance after the embedding of the Ru film 67 (the Ru wire 67a) in the recess 60 may be suppressed. In particular, in the substrate processing apparatus 1 in which the wafers W are transferred among the processing modules 151 to 154 via the first and second substrate transfer chambers 13 and 14, the substrate processing is performed while avoiding exposure to the air, which makes it possible to suppress the formation of an unnecessary natural oxide film.

### Second Embodiment

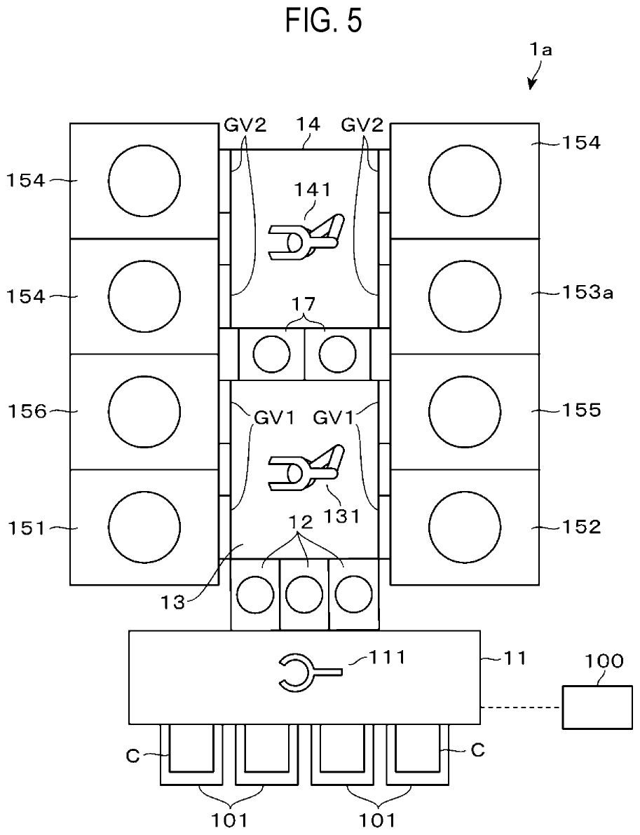

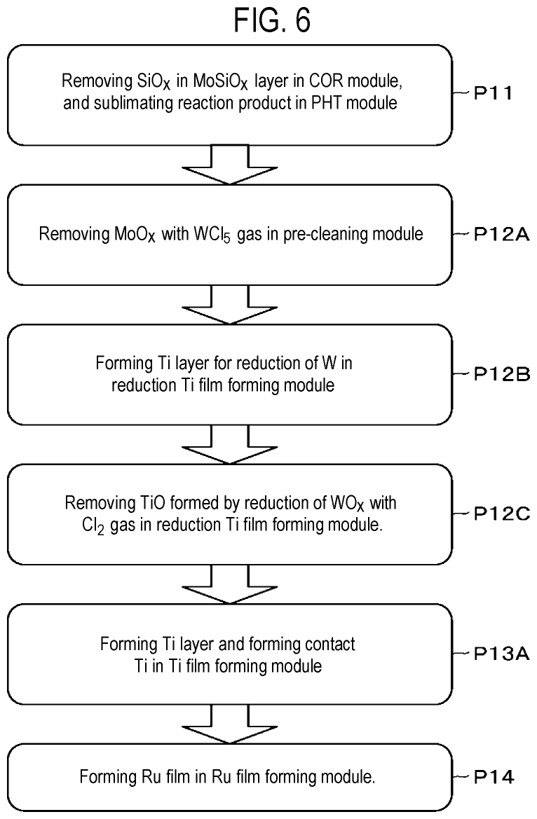

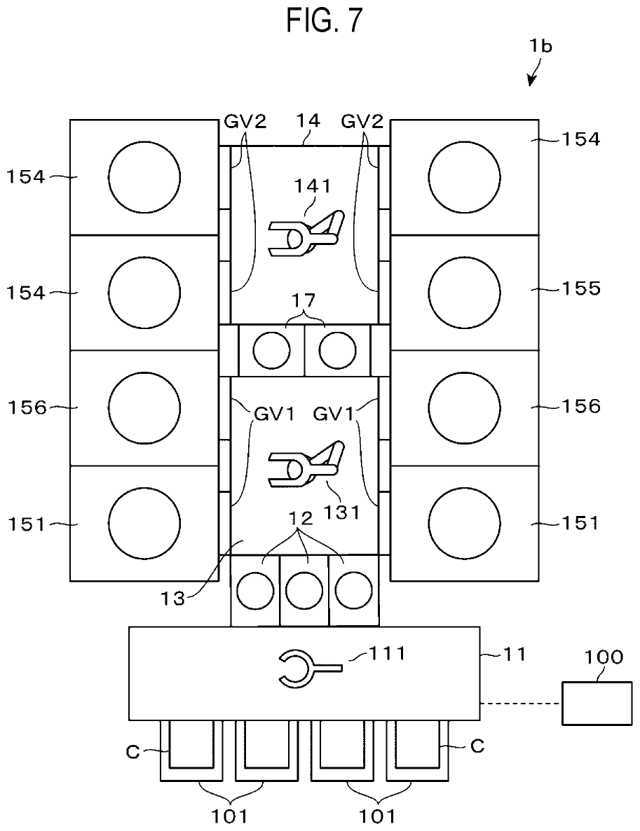

Next, a configuration and operation of the substrate processing apparatus 1a according to the second embodiment will be described with reference to FIGS. 5 and 6. In substrate processing apparatuses 1a and 1b illustrated in FIGS. 5 and 7, the same components as those of the substrate processing apparatus 1 described with reference to FIG. 1 will be denoted by the same reference numerals as those indicated in FIG. 1.

The substrate processing apparatus 1a according to the second embodiment has a configuration that copes with a matter causing a reaction different from that of Equation (1) above when the MoOₓ layer 65b, which is a metal oxide portion, is removed with the WCl₅ gas, which is a metal halide. As will be described later, in such a reaction, an oxide of tungsten (W) (hereinafter, also referred to as “first metal” in the second embodiment) contained in the WCl₅ gas is formed in place of the MoOₓ layer 65b. When the oxide of W remains in the recess 60, since the oxide of W causes an increase in wire resistance after Ru is embedded, it may be necessary to remove the oxide of W in some cases.

Therefore, in order to remove the oxide of W, the substrate processing apparatus 1a of the present embodiment forms a film of a metal that is more easily oxidized than W, such as titanium (Ti) (hereinafter, referred to as a “second metal” in the second embodiment). As a result, the substrate processing apparatus 1a has the configuration in which the oxide of W is reduced by Ti, and the oxide of Ti formed in place of the MoOₓ layer 65b is removed by the etching gas.

From the above point of view, the substrate processing apparatus 1a includes: a pre-cleaning module 156 configured to perform only the removal of the MoOₓ layer 65b with the WCl₅ gas; a reduction Ti film forming module 155 configured to form a Ti film for reducing the oxide of W and remove the oxide of W; and a Ti film forming module 153a configured to form only the Ti layer 66 for contact.

Although individual illustrations are omitted, each of the pre-cleaning module 156, the reduction Ti film forming module 155, and the Ti film forming module 153a is similar in configuration to the Ti film forming module 153 described above with reference to FIG. 2 in that each of the above-mentioned modules includes the processing container 210 and the stage 22.

The pre-cleaning module 156 includes only the metal halide gas supplier (the WCl₅ gas supply pipe 51, the WCl₅ gas source 510, the flow rate regulator M51, and the valve V51) illustrated in FIG. 2, and does not have the configuration for supplying the TiCl₄ gas, the Ar gas, and the H₂ gas for forming the Ti layer 66. Further, the pre-cleaning module 156 does not include the radio-frequency power source 234 for plasmarizing the gas supplied to the processing container 210, the radio-frequency power source 223 for ion attraction, and the like. The pre-cleaning module 156 corresponds to the second processing module of the second embodiment.

The reduction Ti film forming module 155 is substantially similar in configuration to the Ti film forming module 153 illustrated in FIG. 2, and includes a film forming gas supplier configured to supply the film forming gas, which is the mixed gas of the TiCl₄ gas, the H₂ gas, and the Ar gas. On the other hand, the reduction Ti film forming module 155 differs from the Ti film forming module 153 in that an etching gas supplier configured to supply an etching gas for removing the oxide of Ti is provided instead of the supplier configured to supply the WCl₅ gas. In the reduction Ti film forming module 155 of the present example, a chlorine (Cl₂) gas is used as the etching gas. For example, the etching gas supplier includes a Cl₂ gas source, a flow rate regulator, and the like (all not shown).

The Ti film forming module 153a is substantially similar in configuration to the Ti film forming module 153 illustrated in FIG. 2, and includes a film forming gas supplier configured to supply the film forming gas, which is the mixed gas of the TiCl₄ gas, the H₂ gas, and the Ar gas. On the other hand, the Ti film forming module 153a differs from the Ti film forming module 153 in that the metal halide gas supplier configured to supply the WCl₅ gas is not provided. The Ti film forming module 153a corresponds to the third processing module of the present embodiment.

The substrate processing apparatus 1a shown in FIG. 5 differs from the substrate processing apparatus 1 of the first embodiment in that one COR module 151 and one PHT module 152 are connected to the first substrate transfer chamber 13. On the other hand, the substrate processing apparatus 1a of the second embodiment differs from the substrate processing apparatus 1 of the first embodiment in that one pre-cleaning module 156 and one reduction Ti film forming module 155 are connected instead of the two Ti film forming modules 153. Further, one Ti film forming module 153a is connected to the second substrate transfer chamber 14, and three Ru film forming modules 154 are provided.

The processing of the wafer W using the substrate processing apparatus 1a will be described with reference to FIG. 6. In FIG. 6, differences from the substrate processing according to the first embodiment described above with reference to FIG. 3 will be mainly described.

The COR process and the PHT process are performed on the wafer W to be processed by the COR module 151 and the PHT module 152 (Operation P11 in FIG. 6). Thereafter, the wafer W is loaded into the pre-cleaning module 156, and the WCl₅ gas is supplied to remove the MoOₓ layer 65b (Operation P12A in FIG. 6 (operation of removing the metal oxide)).

At this time, as illustrated in FIG. 4B, when the WCl₅ gas reaches the wafer W, a reaction represented in Equation (3) below also proceeds in parallel with the reaction in Equation (1) above.

MoO₃(s)+WCl₅(g)→WO₃(s)+2MoCl₅(g) (3)

Here, the Gibbs free energy when the MoOₓ layer 65b and the WCl₅ gas react in the reaction of Equation (1) is −241 KJ/mol at an absolute temperature of 673K. On the other hand, the Gibbs free energy in the reaction of Equation (3) is −126 KJ/mol under the same temperature condition. Therefore, the Gibbs free energy in both Equations (1) and (3) is negative, and the reaction proceeds in both cases.

By the reaction of Equation (3), while the MoOₓ layer 65b is removed, the oxide of W (WO₃), which is the first metal, is formed on the surface of the wafer W. Therefore, in the substrate processing apparatus 1a of the second embodiment, the wafer W is loaded into the reduction Ti film forming module 155, and the film forming gas is supplied to form the film of Ti for reduction which is the second metal (Operation P12B in FIG. 6). When Ti and WO₃ come into contact with each other due to the formation of the film of Ti for reduction, a reaction of Equation (4) below proceeds so that WO₃ is reduced to become W (operation of reducing the first metal oxide).

WO₃(s)+3Ti(s)→W+3TiO (4)

Thereafter, the supply of the film forming gas is stopped, and the gas supplied into the processing container 210 is switched to the Cl₂ gas. As a result, the reaction represented in Equation (5) below proceeds, and TiO is removed (Operation P12C in FIG. 6 (operation of removing the second metal oxide)).

TiO(s)+Cl₂(g)→TiOCl₂(g) (5)

Through the above-mentioned processes, metallic tungsten (W) remains on the surface of the wafer W. In addition, Ti that did not come into contact with WO₃ also remains on the surface of the wafer W without being etched. Ti formed in the recess 60 is integrated with Ti formed by the Ti film forming module 153a provided in the subsequent stage, to form the Ti layer 66. Further, Ti formed on the surface of the SiO layer 62 is removed by being polished by the CMP process after the Ru film 67 is formed.

As described above, the reaction of Equation (1) proceeds in parallel with the reaction of Equation (3) in which the oxide of W (WO₃) is formed. As a result, when it is undesirable for solid WCl₂ to remain on the surface of the wafer W, for example, the H₂ gas may be supplied before forming the Ti film for reduction so that the reaction of Equation (2) proceeds to remove chlorine, which is the same as in the substrate processing apparatus 1 according to the first embodiment.

At a timing at which the removal of TiO is completed, the wafer W is loaded into the Ti film forming module 153a, and the film forming gas is supplied to form the Ti layer 66, which is a metal layer for contact (Operation P13A in FIG. 6). Thereafter, the operation of forming the Ru film 67 and the operation of unloading the processed wafer W are the same as those in the case of using the substrate processing apparatus 1 described above, and thus redundant description thereof will be omitted.

Here, the second metal is not limited to titanium (Ti). For example, a film of Mo or Ta may be formed as the second metal that is more easily oxidized than tungsten (W), and then the oxide of Mo or Ta may be etched with the chlorine gas.

### Third Embodiment

Next, a configuration and operation of the substrate processing apparatus 1b according to a third embodiment will be described with reference to FIGS. 5 and 6.

The substrate processing apparatus 1b according to the third embodiment is not provided with the PHT module 152 for the PHT process that removes reaction products generated in the COR process. Therefore, the substrate processing apparatus 1b is configured such that the removal of reaction products is performed in parallel with the heating operation of the wafer W when removing the MoOₓ layer 65b by the pre-cleaning module 156.

In the substrate processing apparatus 1b illustrated in FIG. 7, two COR modules 151 and two pre-cleaning modules 156 are connected to the first substrate transfer chamber 13. Therefore, the substrate processing apparatus 1b according to the third embodiment differs from the substrate processing apparatus 1 according to the first embodiment in that no PHT module 152 is provided and that the pre-cleaning module 156, which executes only the removal of the MoOₓ layer 65b, is used. In addition, one Ti film forming module 153a is connected to the second substrate transfer chamber 14, and three Ru film forming modules 154 are provided.

In addition, the substrate processing apparatus 1b in FIG. 7 has a configuration that copes with the proceeding of the reaction of Equation (1) above in the Ti film forming module 153. In the case of coping with the proceeding of the reaction of Equation (3) in the Ti film forming module 153, for example, it may be also possible to employ a configuration in which one COR module 151, one pre-cleaning module 156, and one reduction Ti film forming module 155 are connected to the first substrate transfer chamber 13.

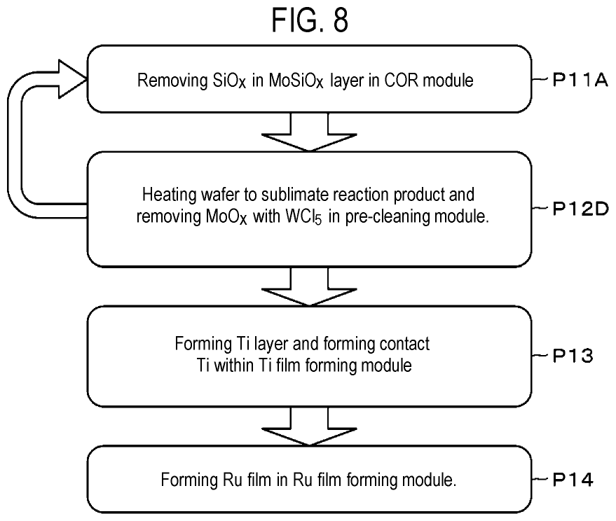

The processing of the wafer W using the substrate processing apparatus 1b will be described with reference to FIG. 8. In FIG. 8, differences from the substrate processing according to the first embodiment described above with reference to FIG. 3 will be mainly described.

First, the COR process is performed on the wafer W to be processed using the COR module 151 (Operation P11A in FIG. 8). Thereafter, the wafer W is loaded into the pre-cleaning module 156 and the WCl₅ gas is supplied to remove the MoOX layer 65b. At this time, the wafer W is heated to a temperature in the range of 400 to 800 degrees C. (e.g., 450 degrees C.), so that the reaction products generated in the COR process are sublimated and removed in parallel with the removal of the MoOₓ layer 65b (Operation P12D in FIG. 8).

Here, FIG. 8 illustrates an example in which the COR process (the removal of silicon oxide (SiOₓ)) in the COR module 151 and the removal of the MoOₓ layer 65b in the pre-cleaning module 156 are repeated multiple times. By repeating these processes, the MoSiOₓ layer 65a on the surface of the MoSi layer 64 may be reliably removed. For example, the number of repetitions of these processes may range from 2 to 10 times.

In particular, the substrate processing apparatus 1b according to the third embodiment illustrated in FIG. 7 may be configured such that the PHT module 152 is not installed, and the removal of the reaction products by the COR process and the removal of the MoOₓ layer 65b are performed in parallel within the pre-cleaning module 156. Therefore, a processing time per cycle may be shortened compared to the case where the processes are repeated by using three processing modules (the COR module 151, the PHT module 152, and the Ti film forming module 153).

In addition, in the example of the substrate processing apparatus 1b illustrated in FIG. 7, two sets of COR modules 151 and Ti film forming modules 153 may be provided to suppress the total processing time from being excessively increased due to the repetitive execution of the processes.

However, even when the COR process and the process using WCl₅ gas are repeated multiple times, the execution of the PHT process using the PHT module 152 is not excluded. The processes using the COR module 151, the PHT module 152, and the Ti film forming module 153 may be repeated.

When both the COR process and the PHT process are repeated a predetermined number of times and the MoSiOₓ layer 65a is removed, the Ti layer 66 for contact is formed by the Ti film forming module 153a, and the Ru film 67 is formed by the Ru film forming module 154. The subsequent operation of unloading the wafer W is the same as that in the case of using the above-described substrate processing apparatus 1, and therefore, a redundant description thereof is omitted.

### Variations

In each of the embodiments described above, the metal halide gas used to remove the metal oxide component (the MoOₓ layer 65b) on the surface of the MoSi layer 64 is not limited to the WCl₅ gas exemplified herein. For example, the MoOX layer 65b may be removed with a WCl₆ gas or a MoCl₅ gas.

In addition, the configuration of the silicon-containing layer is not limited to the SiGe layer 61 exemplified with reference to FIG. 4A, and may be a single silicon layer containing no germanium. Further, the configuration of the metal silicide layer is not limited to the MoSi layer 64 exemplified herein but a TiSi layer or a WSi layer may be used. Even when oxide films are formed on surfaces of these metal silicides, they may be removed by a combination of the COR process and a process using the metal halide gas.

Further, in the removal of the silicon oxide portion by the COR process (the HF gas and the NH₃ gas) and the removal of the metal oxide portion by the metal halide gas, the COR process does not necessarily have to be executed preferentially. The COR process may be performed after the execution of the processes using the metal halide gas.

According to the present disclosure, it is possible to remove an oxide film on a surface of a metal silicide layer formed in a recess of a substrate.

It should be noted that the embodiments disclosed in the present disclosure are merely exemplary in all respects and are not to be construed in a limited way. The above-described embodiments may be omitted, replaced and changed in various forms without departing from the appended claims and the gist thereof.

What is claimed is:

1. A method of processing a substrate, the method comprising:
removing a silicon oxide portion contained in an oxide film on a surface of a metal silicide layer by supplying a hydrogen fluoride gas and an ammonia gas to the oxide film so as to react with the silicon oxide portion contained in the oxide film, wherein the metal silicide layer is provided by being stacked in a recess formed in an insulator layer which is stacked on a silicon-containing layer; and
removing a metal oxide portion by supplying a metal halide gas to the oxide film so as to react with the metal oxide portion contained in the oxide film.

2. The method of claim 1, wherein the removing the silicon oxide portion includes removing a reaction product by heating the substrate, wherein the reaction product is produced by the reaction of the silicon oxide portion with the hydrogen fluoride gas and the ammonia gas.

3. The method of claim 1, wherein, after the removing the silicon oxide portion, in a state in which the substrate is heated, the removing the metal oxide portion is executed such that the removing the metal oxide portion and removing a reaction product produced by the reaction of the silicon oxide portion with the hydrogen fluoride gas and the ammonia gas are executed in parallel.

4. The method of claim 1, wherein the removing the silicon oxide portion and the removing the metal oxide portion are repeatedly executed.

5. The method of claim 1, wherein the silicon-containing layer is a silicon germanium layer, the metal silicide layer is a molybdenum silicide layer, and the metal oxide portion is a molybdenum oxide.

6. The method of claim 1, wherein the metal halide gas is a WCl₅ gas or a MoCl₅ gas.

7. The method of claim 1, further comprising:
when an oxide of a first metal contained in the metal halide remains on the substrate in place of the metal oxide portion in the removing the metal oxide portion, reducing the oxide of the first metal by forming a film of a second metal, which is more easily oxidized than the first metal, on the substrate on which the oxide of the first metal remains; and
subsequently, removing, by an etching gas, an oxide of the second metal formed in place of the oxide of the first metal in the reducing the oxide of the first metal.

8. The method of claim 7, wherein the first metal is tungsten, and the second metal is titanium.

9. The method of claim 8, wherein the etching gas is a chlorine gas.

10. The method of claim 1, further comprising:
after executing the removing the silicon oxide portion and the removing the metal oxide portion, forming a film of a conductor on the substrate to embed the conductor in the recess.

11. An apparatus for processing a substrate, comprising:
a first processing module including a first processing container equipped with a first stage on which the substrate is placed, and a mixed-gas supplier configured to supply a mixed gas of a hydrogen fluoride gas and an ammonia gas to the first processing container;
a second processing module including a second processing container equipped with a second stage on which the substrate is placed, and a metal halide gas supplier configured to supply a metal halide gas to the second processing container; and
a controller,
wherein the controller is configured to output a first control signal for executing:
removing a silicon oxide portion contained in an oxide film on a surface of a metal silicide layer by supplying the mixed gas to the oxide film so as to react with the silicon oxide portion contained in the oxide film, wherein the metal silicide layer is provided by being stacked in a recess formed in an insulator layer which is stacked on a silicon-containing layer; and
removing a metal oxide portion by supplying the metal halide gas to the oxide film so as to react with the metal oxide portion contained in the oxide film.

12. The apparatus of claim 11, further comprising:
a vacuum transfer chamber to which the first processing container of the first processing module and the second processing container of the second processing module are connected; and
a substrate transfer mechanism disposed within the vacuum transfer chamber,
wherein the controller is configured to output a second control signal for executing:
transferring, by the substrate transfer mechanism, the substrate between the first stage of the first processing module and the second stage of the second processing module via the vacuum transfer chamber between the removing the silicon oxide portion and the removing the metal oxide portion.

13. The apparatus of claim 11, wherein the second processing module includes a heater configured to heat the substrate, and
wherein the controller is configured to output a third control signal for executing
after the removing the silicon oxide portion, in a state in which the substrate is heated, the removing the metal oxide portion such that the removing the metal oxide portion and removing a reaction product produced by the reaction of the silicon oxide portion with the hydrogen fluoride gas and the ammonia gas are executed in parallel.

14. The apparatus of claim 11, wherein the silicon-containing layer is a silicon germanium layer, the metal silicide layer is a molybdenum silicide layer, and the metal oxide portion is a molybdenum oxide.

15. The apparatus of claim 11, wherein the metal halide gas is a WCl₅ gas or a MoCl₅ gas.

16. The apparatus of claim 11, further comprising: a third processing module,
wherein the third processing module includes:
a third processing container equipped with a third stage on which the substrate is placed;
a film forming gas supplier configured to supply, to the third processing container, a gas for forming a film of a second metal, which is more easily oxidized than a first metal contained in the metal halide; and
an etching gas supplier configured to supply an etching gas for etching an oxide of the second metal, and
wherein the controller is configured to output a fourth control signal for executing:
when an oxide of the first metal remains on the substrate in place of the metal oxide portion in the removing the metal oxide portion, reducing the oxide of the first metal by supplying the film-forming gas to the substrate on which the oxide of the first metal remains to form the film of the second metal on the substrate; and subsequently, removing, by the etching gas, the oxide of the second metal formed in place of the oxide of the first metal in the reducing the oxide of the first metal.

17. The apparatus of claim 16, wherein the first metal is tungsten, and the second metal is titanium.

18. The apparatus of claim 17, wherein the etching gas is a chlorine gas.

19. The apparatus of claim 11, further comprising: a fourth processing module,
wherein the fourth processing module includes:
a fourth processing container equipped with a fourth stage on which the substrate is placed; and
a raw material gas supplier configured to supply a raw material gas for a conductor to the fourth processing container, and
wherein the controller is configured to output a fourth control signal for executing:
placing the substrate on the fourth stage of the fourth processing module after executing the removing the silicon oxide portion and the removing the metal oxide portion, and supplying the raw material gas into the fourth processing container to form a film of the conductor on the substrate and embed the conductor in the recess.
